(19) United States
(12) Patent Application Publication
(10) Pub. No.: US 2013/0075766 A1
(43) Pub. Date: Mar. 28, 2013

(54) THIN FILM TRANSISTOR DEVICE AND PIXEL STRUCTURE AND DRIVING CIRCUIT OF A DISPLAY PANEL

(71) Applicants: Che-Chia Chang, Hsin-Chu (TW); Sheng-Chao Liu, Hsin-Chu (TW); Wu-Liu Tsai, Hsin-Chu (TW); Chuan-Sheng Wei, Hsin-Chu (TW); Chih-Hung Lin, Hsin-Chu (TW)

(72) Inventors: Che-Chia Chang, Hsin-Chu (TW); Sheng-Chao Liu, Hsin-Chu (TW); Wu-Liu Tsai, Hsin-Chu (TW); Chuan-Sheng Wei, Hsin-Chu (TW); Chih-Hung Lin, Hsin-Chu (TW)

(21) Appl. No.: 13/448,359

(22) Filed: Apr. 16, 2012

(30) Foreign Application Priority Data
Sep. 22, 2011 (TW) 100134107

(51) Int. Cl. H01L 27/15; H01L 27/105

(52) U.S. Cl. 257/88; 257/306; 257/E27.081; 257/E27.12

(57) ABSTRACT

A thin film transistor device, disposed on a substrate, includes a gate electrode, a semiconductor channel layer, a gate insulating layer disposed between the gate electrode and the semiconductor channel layer, a source electrode and a drain electrode disposed at two opposite sides of the semiconductor channel layer and partially overlapping the semiconductor channel layer, respectively, a capacitor electrode at least partially overlapping the gate electrode, and a capacitor dielectric layer disposed between the capacitor electrode and the gate electrode. The capacitor electrode, the gate electrode and the capacitor dielectric layer form a capacitor device.

### BACKGROUND OF THE INVENTION

1. Field of the Invention

The invention relates to a thin film transistor device, and a pixel structure and a driving circuit of a display panel, and more particularly, to a pixel structure and a driving circuit of a display panel including the aforementioned thin film transistor device.

2. Description of the Prior Art

Flat display panel, such as liquid crystal display (LCD) panel, has replaced conventional cathode ray tube (CRT) display panel and prevailed display market for its advantages of compact size, low radiation and low power consumption. In the development of flat display panels, slim border (slim bezel) design and high resolution specification are two principle trends. In conventional flat display panel, attempts have been made to integrate the gate driving circuit into the array substrate (normally referred to gate driver on array circuit, GOA circuit) for reducing the number of gate driving ICs. However, with the increase of resolution, the peripheral area for accommodating the GOA driver has to be increased. Consequently, the board of the flat display panel cannot be further reduced, which adversely affects the development of slim border flat display panel.

### SUMMARY OF THE INVENTION

It is one of the objectives of this invention to provide a thin film transistor device, and a pixel structure and a driving circuit of a display panel to increase the aperture ratio of the pixel structure and to reduce the border of display panel.

According to a preferred embodiment of this invention, a thin film transistor device disposed on a substrate is provided. the thin film transistor device includes a gate electrode, a semiconductor channel layer, a gate insulating layer disposed between the gate electrode and the semiconductor channel layer, a source electrode and a drain electrode disposed at two opposite sides of the semiconductor channel layer and partially overlapping the gate electrode, respectively, a capacitor electrode at least partially overlapping the gate electrode, and a capacitor dielectric layer disposed between the capacitor electrode and the gate electrode. The capacitor electrode, the gate electrode and the capacitor dielectric layer form a capacitor device.

According to another preferred embodiment of this invention, a pixel structure of a display panel disposed on a substrate is provided. The pixel structure of the display panel includes a thin film transistor device and a pixel electrode. The thin film transistor device includes a gate electrode, a semiconductor channel layer, a gate insulating layer disposed between the gate electrode and the semiconductor channel layer, a source electrode and a drain electrode disposed at two opposite sides of the semiconductor channel layer and partially overlapping the gate electrode, respectively, a capacitor electrode at least partially overlapping the gate electrode, and a capacitor dielectric layer disposed between the capacitor electrode and the gate electrode. The pixel electrode is electrically connected to the drain electrode and the capacitor electrode, respectively. The capacitor electrode, the gate electrode and the capacitor dielectric layer form a capacitor device.

According to still another preferred embodiment of this invention, a driving circuit of a display panel is provided. The driving circuit of the display panel includes a plurality of driving units. Each of the driving units includes a thin film transistor device and a capacitor device. The thin film transistor device includes a gate electrode, a semiconductor channel layer, a gate insulating layer disposed between the gate electrode and the semiconductor channel layer, and a source electrode and a drain electrode disposed at two opposite sides of the semiconductor channel layer and partially overlapping the gate electrode, respectively. The capacitor device includes a capacitor electrode at least partially overlapping the gate electrode of the thin film transistor device, a capacitor dielectric layer disposed between the capacitor electrode and the gate electrode, and the gate electrode of the thin film transistor device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a thin film transistor device according to a first preferred embodiment of the invention.

FIG. 2 is a schematic diagram illustrating a thin film transistor device according to a second preferred embodiment of the invention.

FIG. 3 is a schematic diagram illustrating a thin film transistor device according to a variant embodiment of the second preferred embodiment of the invention.

FIG. 4 is a schematic diagram illustrating a pixel structure of a display panel according to a preferred embodiment of this invention.

FIG. 5 is an equivalent circuit diagram of the pixel structure of the display panel of FIG. 4.

FIG. 6 is a schematic diagram illustrating a driving circuit of a display panel according to another embodiment of this invention.

### DETAILED DESCRIPTION

To provide a better understanding of the present invention to the skilled users in the technology of the present invention, preferred embodiments will be detailed as follows. The preferred embodiments of the present invention are illustrated in the accompanying drawings with numbered elements to elaborate the contents and effects to be achieved.

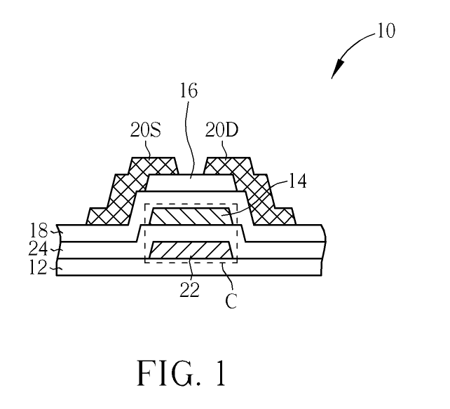

Please refer to FIG. 1. FIG. 1 is a schematic diagram illustrating a thin film transistor device according to a first preferred embodiment of the invention. As shown in FIG. 1, the thin film transistor (TFT) device 10 of this embodiment is disposed on a substrate 12 e.g. an array substrate of a display panel. The TFT device 10 includes a gate electrode 14, a semiconductor channel layer 16, a gate insulating layer 18, a source electrode 20S and a drain electrode 20D, a capacitor electrode 22 and a capacitor dielectric layer 24. The gate insulating layer 18 is disposed between the gate electrode 14 and the semiconductor channel layer 16; the source electrode 20S and the drain electrode 20D are disposed at two opposite sides of the semiconductor channel layer 16 and partially overlaps the semiconductor channel layer 16, respectively. The capacitor dielectric layer 24 is disposed between the capacitor electrode 22 and the gate electrode 14. The capacitor electrode 22 at least partially overlaps the gate electrode 14, and the capacitor electrode 22, the gate electrode 14 and the capacitor dielectric layer 24 form a capacitor device C. In this embodiment, the gate electrode 14 not only serves as the gate electrode of the TFT device 10, but also serves as the other capacitor electrode of the capacitor device C. The capacitor electrode 22 is substantially corresponding to the gate electrode 14, i.e. the capacitor electrode 22 and the gate electrode 14 have substantially the same dimensions, but not limited thereto. For example, the dimension of the capacitor electrode 22 may be larger and smaller than that of the gate electrode 14. In this embodiment, the TFT device 10 is a bottom gate type TFT device. The capacitor dielectric layer 24 is disposed on the capacitor electrode 22, the gate electrode 14 is disposed on the capacitor dielectric layer 24, the gate insulating layer 18 is disposed on the gate electrode 14, the semiconductor channel layer 16 is disposed on the gate insulating layer 18, and the source electrode 20S and the drain electrode 20D are at least disposed on the semiconductor channel layer 16. In addition, ohmic contact layers (not shown) may be disposed between the source electrode 20S and the semiconductor channel layer 22 and between the drain electrode 20D and the semiconductor channel layer 16, respectively. The capacitance of the capacitor device C is proportional to the area of the capacitor electrode 22. Thus, the area of the capacitor electrode 22 is enlarged when the required capacitance is high. As shown in FIG. 1, the capacitor electrode 22 and the gate electrode 14 overlap in a vertical projection direction, and thus the capacitor device C does not occupy extra area of the substrate 12. Consequently, the integration level can be effectively increased.

The TFT device is not limited by the aforementioned embodiment, and may have other different preferred embodiments. To simplify the description, the identical components in each of the following embodiments are marked with identical symbols. For making it easier to compare the difference between the embodiments, the following description will detail the dissimilarities among different embodiments and the identical features will not be redundantly described.

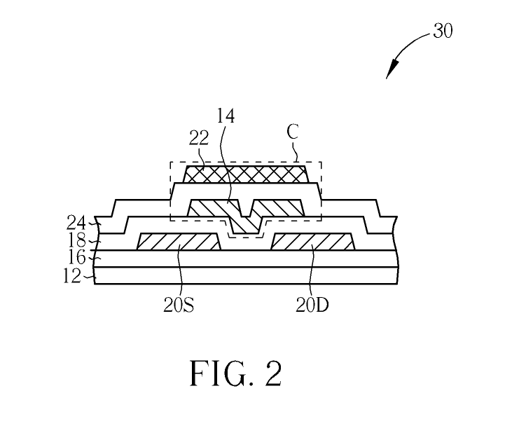

Please refer to FIG. 2. FIG. 2 is a schematic diagram illustrating a thin film transistor device according to a second preferred embodiment of the invention. As shown in FIG. 2, different from the first preferred embodiment, the TFT device 30 of this embodiment is a top gate type TFT device. The semiconductor channel layer 16 is disposed on the substrate 12, the source electrode 20S and the drain electrode 20D are disposed on the semiconductor channel layer 16, the gate insulating layer 18 is disposed on the semiconductor channel layer 16, the source electrode 20S and the drain electrode 20D, the gate electrode 14 is disposed on the gate insulating layer 18, the capacitor dielectric layer 24 is disposed on the gate electrode 14, and the capacitor electrode 22 is disposed on the capacitor dielectric layer 24. The capacitor electrode 22 at least partially overlaps the gate electrode 14, and the capacitor electrode 22, the gate electrode 14 and the capacitor dielectric layer 24 form a capacitor device C.

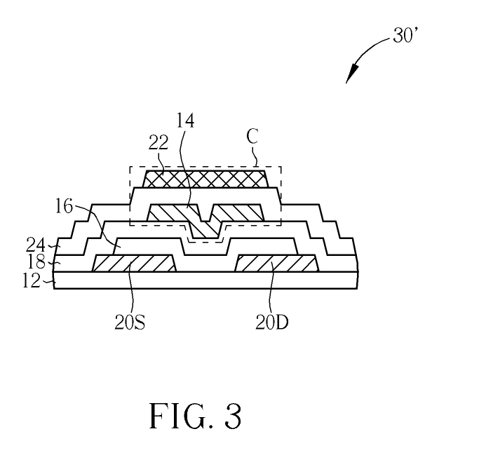

Please refer to FIG. 3. FIG. 3 is a schematic diagram illustrating a thin film transistor device according to a variant embodiment of the second preferred embodiment of the invention. As shown in FIG. 3, different from the second preferred embodiment, in the TFT device 30′ of this variant embodiment, the source electrode 20S and the drain electrode 20D are disposed on the substrate 12, the semiconductor channel layer 16 is disposed on the substrate 12, the source electrode 20S and the drain electrode 20D, the gate insulating layer 18 is disposed on the semiconductor channel layer 16, the gate electrode 14 is disposed on the gate insulating layer 18, the capacitor dielectric layer 24 is disposed on the gate electrode 14, and the capacitor electrode 22 is disposed on the capacitor dielectric layer 24. The capacitor electrode 22 at least partially overlaps the gate electrode 14, and the capacitor electrode 22, the gate electrode 14 and the capacitor dielectric layer 24 form a capacitor device C.

In this invention, the capacitor electrode and the gate electrode can from a capacitor device, and the capacitor electrode and the gate electrode are overlapping in the vertical projection direction; thus, no extra area of the substrate is occupied, which increases the integration level. The TFT device of this invention can be applied in any electronic device in which an electrical connection between the capacitor device and the gate electrode of the TFT device is required, and the application examples of the TFT device of this invention will be described in the following passages.

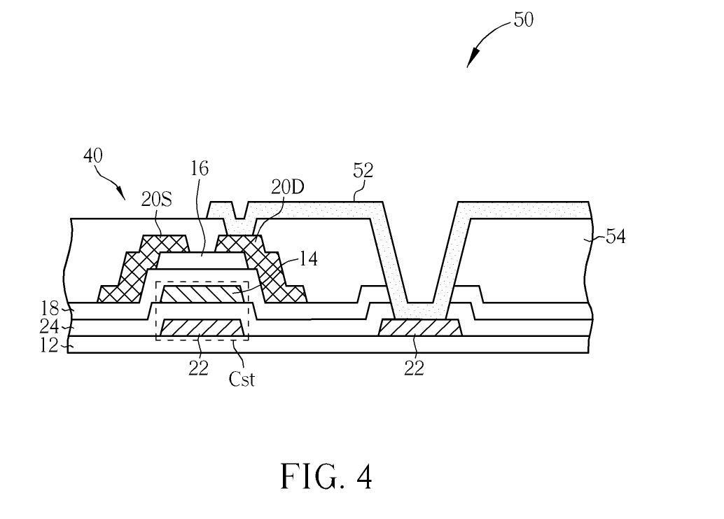

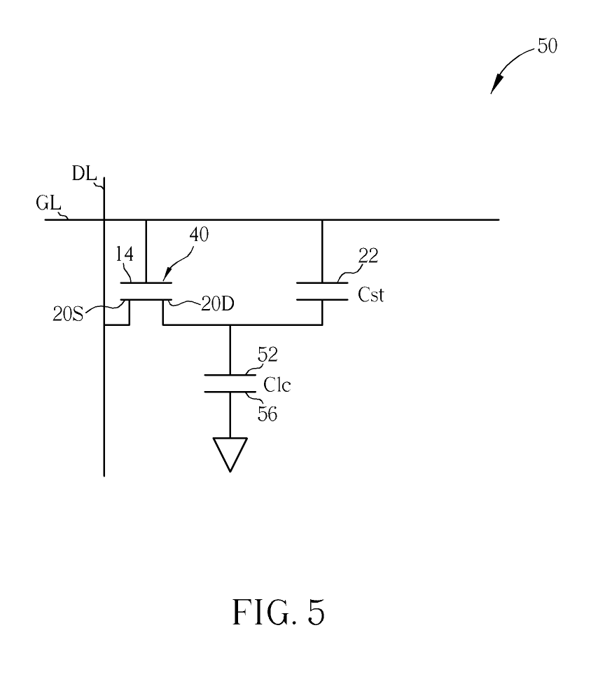

Please refer to FIG. 4 and FIG. 5, as well as FIGS. 1-3. FIG. 4 is a schematic diagram illustrating a pixel structure of a display panel according to a preferred embodiment of this invention, and FIG. 5 is an equivalent circuit diagram of the pixel structure of the display panel of FIG. 4. As shown in FIG. 4 and FIG. 5, the pixel structure 50 of the display panel may be e.g. a pixel structure of an LCD panel, disposed on a substrate 12. The pixel structure 50 of the display panel includes a gate line GL, a data line DL, a TFT device 40 and a pixel electrode 52. The TFT device 40 includes a gate electrode 14, a semiconductor channel layer 16, a gate insulating layer 18 disposed between the gate electrode 14 and the semiconductor channel layer 16, a source electrode 20S and a drain electrode 20D disposed at two opposite sides of the semiconductor channel layer 16 and partially overlaps the semiconductor channel layer 16, respectively, a capacitor electrode 22 at least partially overlapping the gate electrode 14, and a capacitor dielectric layer 24 disposed between the capacitor electrode 22 and the gate electrode 14. In this embodiment, the TFT device 40 of the pixel structure 50 of the display panel may be selected from the TFT device of the first preferred embodiment, the second preferred embodiment and a variant embodiment thereof. The pixel electrode 52 is disposed on a passivation layer 54. The passivation layer 54 partially exposes the drain electrode 20D of the TFT device 40, such that the pixel electrode 52 can be electrically connected to the drain electrode 20D. The pixel structure 50 of the display panel further includes a common electrode 56 (not shown in FIG. 4) and a liquid crystal layer (not shown), and the pixel electrode 52, the common electrode 56 and the liquid crystal layer disposed therebetween form a liquid crystal capacitor Clc. In addition, an extension part of the capacitor electrode 22 is disposed under the pixel electrode 52, and partially exposed by the passivation layer 54, the gate insulating layer 18 and the capacitor dielectric layer 24, such that the pixel electrode 52 can be electrically connected to the capacitor electrode 22. The capacitor electrode 22, the gate electrode 14 and the capacitor dielectric layer 24 from a storage capacitor device Cst. Since a portion of the capacitor electrode 22 overlaps the gate electrode 14 in the vertical projection direction, and thus the aperture ratio of the pixel structure 50 of the display panel can be improved. In this embodiment, the capacitor electrode 22 corresponding to the gate electrode 14 and the extension part of the capacitor electrode 22 that electrically connects with the pixel electrode 52 may be made of the same patterned conductive layer, but not limited thereto. For instance, the capacitor electrode 22 corresponding to the gate electrode 14 and the extension part of the capacitor electrode 22 that electrically connects with the pixel electrode 52 may be made of different patterned conductive layers, and electrically connected to each other in a bridge connection manner.

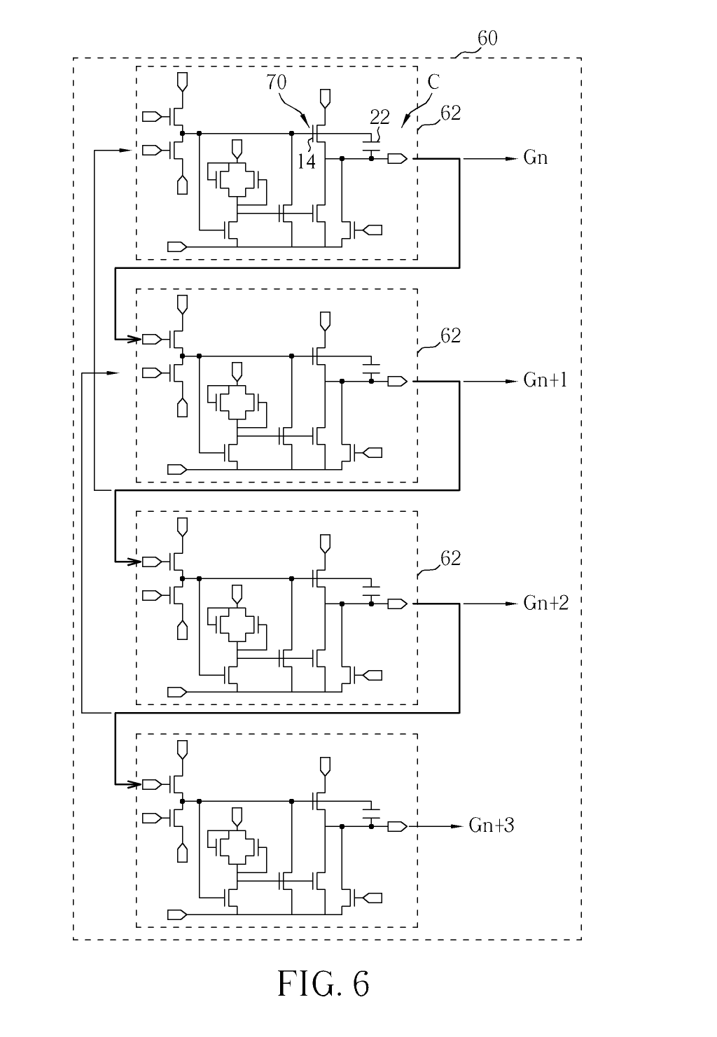

Please refer to FIG. 6, as well as FIGS. 1-3. FIG. 6 is a schematic diagram illustrating a driving circuit of a display panel according to another embodiment of this invention. As shown in FIG. 6, the driving circuit 60 of the display panel of this embodiment includes a plurality of driving units 62. In this embodiment, a gate driving circuit is selected as an example of the driving circuit 60 of the display panel. In such a case, each of the driving units 62 may be a shift register circuit unit. Each driving unit 62 includes the TFT device of the first preferred embodiment, the second preferred embodiment and a variant embodiment thereof. The capacitor device C of the driving unit 62 and the gate electrode 14 of the TFT device 70 are electrically connected to each other. Specifically, the capacitor electrode 22 and the gate electrode 14 form the capacitor device C, and the capacitor electrode 22 at least partially overlaps the gate electrode 14. In addition, the driving units 62 are electrically connected to the corresponding gate lines such as the gate line Gn, the gate line Gn+1, the gate line Gn+2, the gate line Gn+3. In this embodiment, the driving circuit 60 of the display panel is used to providing the gate driving signals fro the display panel. Since the capacitor electrode 22 and the gate electrode 14 of the driving unit 62 overlap to each other in the vertical projection direction, the capacitor device C does not occupy extra area of the peripheral region. Thus, the dimension of the driving circuit of the display panel can be reduced to meet the slim border requirement.

In conclusion, the vertically-stacked capacitor device and the TFT device do not occupy extra area, which thus can increase the integration level. In the application of high resolution flat display panel, particularly, the layout area of the peripheral circuit can be dramatically reduced, and thus slim border design can be fulfilled.

Those skilled in the art will readily observe that numerous modifications and alterations of the device and method may be made while retaining the teachings of the invention.

Accordingly, the above disclosure should be construed as limited only by the metes and bounds of the appended claims.

What is claimed is:

1. A thin film transistor device, disposed on a substrate, the thin film transistor device comprising:
a gate electrode;
a semiconductor channel layer;
a gate insulating layer, disposed between the gate electrode and the semiconductor channel layer;
a source electrode and a drain electrode, disposed at two opposite sides of the semiconductor channel layer and partially overlapping the gate electrode, respectively;
a capacitor electrode, at least partially overlapping the gate electrode; and
a capacitor dielectric layer, disposed between the capacitor electrode and the gate electrode, wherein the capacitor electrode, the gate electrode and the capacitor dielectric layer form a capacitor device.

2. The thin film transistor device of claim 1, wherein the capacitor dielectric layer is disposed on the capacitor electrode, the gate electrode is disposed on the capacitor dielectric layer, the gate insulating layer is disposed on the gate electrode, the semiconductor channel layer is disposed on the gate insulating layer, and the source electrode and the drain electrode are at least disposed on the semiconductor channel layer.

3. The thin film transistor device of claim 1, wherein the semiconductor channel layer is disposed on the substrate, the source electrode and the drain electrode, the gate insulating layer is disposed on the semiconductor channel layer, the gate electrode is disposed on the gate insulating layer, the capacitor dielectric layer is disposed on the gate electrode, and the capacitor electrode is disposed on the capacitor dielectric layer.

4. The thin film transistor device of claim 1, wherein the source electrode and the drain electrode are disposed on the semiconductor channel layer, the gate insulating layer is disposed on the semiconductor channel layer, the source electrode and the drain electrode, the gate electrode is disposed on the gate insulating layer, the capacitor dielectric layer is disposed on the gate electrode, and the capacitor electrode is disposed on the capacitor dielectric layer.

5. The thin film transistor device of claim 1, wherein the capacitor electrode is substantially corresponding to the gate electrode.

6. A pixel structure of a display panel, disposed on a substrate, the pixel structure of the display panel comprising:
a thin film transistor device, comprising:
a gate electrode;
a semiconductor channel layer;
a gate insulating layer, disposed between the gate electrode and the semiconductor channel layer;
a source electrode and a drain electrode, disposed at two opposite sides of the semiconductor channel layer and partially overlapping the gate electrode, respectively;
a capacitor electrode, at least partially overlapping the gate electrode; and
a capacitor dielectric layer, disposed between the capacitor electrode and the gate electrode; and
a pixel electrode, electrically connected to the drain electrode and the capacitor electrode, respectively;
wherein the capacitor electrode, the gate electrode and the capacitor dielectric layer form a capacitor device.

7. The pixel structure of the display panel of claim 6, wherein the capacitor dielectric layer is disposed on the capacitor electrode, the gate electrode is disposed on the capacitor dielectric layer, the gate insulating layer is disposed on the gate electrode, the semiconductor channel layer is disposed on the gate insulating layer, and the source electrode and the drain electrode are at least disposed on the semiconductor channel layer.

8. The pixel structure of the display panel of claim 6, wherein the semiconductor channel layer is disposed on the substrate, the source electrode and the drain electrode, the gate insulating layer is disposed on the semiconductor channel layer, the gate electrode is disposed on the gate insulating layer, the capacitor dielectric layer is disposed on the gate electrode, and the capacitor electrode is disposed on the capacitor dielectric layer.

9. The pixel structure of the display panel of claim 6, wherein the source electrode and the drain electrode are disposed on the semiconductor channel layer, the gate insulating layer is disposed on the semiconductor channel layer, the source electrode and the drain electrode, the gate electrode is disposed on the gate insulating layer, the capacitor dielectric layer is disposed on the gate electrode, and the capacitor electrode is disposed on the capacitor dielectric layer.

10. The pixel structure of the display panel of claim 6, wherein the capacitor electrode is substantially corresponding to the gate electrode.

11. A driving circuit of a display panel, comprising:
a plurality of driving units, each of the driving units comprising:
a thin film transistor device, comprising:
a gate electrode;
a semiconductor channel layer;
a gate insulating layer, disposed between the gate electrode and the semiconductor channel layer; and
a source electrode and a drain electrode, disposed at two opposite sides of the semiconductor channel layer and partially overlapping the gate electrode, respectively;
a capacitor device, comprising:
a capacitor electrode, at least partially overlapping the gate electrode of the thin film transistor device;
a capacitor dielectric layer, disposed between the capacitor electrode and the gate electrode; and
the gate electrode of the thin film transistor device.

12. The driving circuit of the display panel of claim 11, further comprising a gate driving circuit, wherein each of the driving units comprises a shift register circuit unit, and each of the driving units is electrically connected to a gate line.

13. The driving circuit of the display panel of claim 11, wherein the capacitor dielectric layer is disposed on the capacitor electrode, the gate electrode is disposed on the capacitor dielectric layer, the gate insulating layer is disposed on the gate electrode, the semiconductor channel layer is disposed on the gate insulating layer, and the source electrode and the drain electrode are at least disposed on the semiconductor channel layer.

14. The driving circuit of the display panel of claim 11, wherein the semiconductor channel layer is disposed on the substrate, the source electrode and the drain electrode, the gate insulating layer is disposed on the semiconductor channel layer, the gate electrode is disposed on the gate insulating layer, the capacitor dielectric layer is disposed on the gate electrode, and the capacitor electrode is disposed on the capacitor dielectric layer.

15. The driving circuit of the display panel of claim 11, wherein the source electrode and the drain electrode are disposed on the semiconductor channel layer, the gate insulating layer is disposed on the semiconductor channel layer, the source electrode and the drain electrode, the gate electrode is disposed on the gate insulating layer, the capacitor dielectric layer is disposed on the gate electrode, and the capacitor electrode is disposed on the capacitor dielectric layer.

16. The driving circuit of the display panel of claim 11, wherein the capacitor electrode is substantially corresponding to the gate electrode.
